(19) United States
(12) Patent Application Publication
(10) Pub. No.: US 2025/0232994 A1
(43) Pub. Date: Jul. 17, 2025

(54) Substrate Transfer Module and Method for Manufacturing Substrate Transfer Module

(71) Applicant: Tokyo Electron Limited, Tokyo (JP)

(72) Inventor: Akinori SHIMAMURA, Yamanashi (JP)

(21) Appl. No.: 19/011,360

(22) Filed: Jan. 6, 2025

(30) Foreign Application Priority Data
Jan. 17, 2024 (JP) 2024-005425

(51) Int. Cl. H01L 21/673; H01F 27/28; H01F 27/32; H01L 21/677

(52) U.S. Cl. CPC H01L 21/67323; H01F 27/2823; H01F 27/323; H01L 21/67709

(57) ABSTRACT

Provided is a substrate transfer module that constitutes a semiconductor manufacturing apparatus for processing a substrate and transfers the substrate in a transfer space having a vacuum atmosphere, the substrate transfer module comprising: a chamber that defines the transfer space and includes a floor on which a tile is provided, the tile including an electromagnet for forming a magnetic field that acts on a magnet provided on a transfer body for transferring the substrate in the transfer space and moves the transfer body in a levitated state, wherein a coating film is formed on at least a surface of the tile contacting the transfer space to suppress release of contaminants from components that constitute the tile.

### CROSS-REFERENCE TO RELATED APPLICATIONS

This application claims priority to Japanese Patent Application No. 2024-005425 filed on Jan. 17, 2024, the entire contents of which are incorporated herein by reference.

### TECHNICAL FIELD

The present disclosure relates to a substrate transfer module and a method for manufacturing the substrate transfer module.

### BACKGROUND

For example, in a substrate processing apparatus that performs processing on a semiconductor wafer (hereinafter referred to as a “wafer”), which is a substrate, the wafer is transferred between a carrier that accommodates the wafer and a substrate processing chamber in which the processing is performed. Various types of substrate transfer mechanisms are used to transfer the wafer. The applicant is currently developing a substrate processing apparatus that transfers the substrate using a substrate transfer body that utilizes magnetic levitation.

As an example of magnetic levitation technology, Japanese Laid-open Patent Publication No. 2014-531189 discloses a displacement device that includes a stator having a coil, and a movable stage that may have a magnet array and support a semiconductor wafer. Further, a technique for arranging the magnet array to move the movable stage relative to the stator is also described.

### SUMMARY

The present disclosure provides a technique for suppressing the release of contaminants from a tile, intended to move a transfer body that transfers a substrate under a vacuum atmosphere using magnetic levitation, in a substrate transfer module of a semiconductor manufacturing apparatus that performs processing on the surface of the substrate.

In accordance with an aspect of the subject application, there is provided a substrate transfer module that constitutes a semiconductor manufacturing apparatus for processing a substrate and transfers the substrate in a transfer space having a vacuum atmosphere, the substrate transfer module comprising: a chamber that defines the transfer space and includes a floor on which a tile is provided, the tile including an electromagnet for forming a magnetic field that acts on a magnet provided on a transfer body for transferring the substrate in the transfer space and moves the transfer body in a levitated state, wherein a coating film is formed on at least a surface of the tile contacting the transfer space to suppress release of contaminants from components that constitute the tile.

### BRIEF DESCRIPTION OF THE DRAWINGS

FIG. 1 is a plan view illustrating a configuration example of a substrate processing apparatus according to an embodiment.

FIG. 2 is a perspective view illustrating a transfer body and a floor according to an embodiment.

FIG. 3 is a longitudinal side view of the transfer body.

FIG. 4 is a partially exploded view of the floor.

FIG. 5 is an enlarged view of a coil portion provided on the floor.

FIG. 6 is a schematic view illustrating the configuration of a film forming apparatus.

FIG. 7 is a longitudinal side view illustrating a tile according to a modification of the present embodiment.

FIG. 8 is a plan view illustrating a tile attaching method according to a modification.

### DETAILED DESCRIPTION

### <Substrate Processing Apparatus>

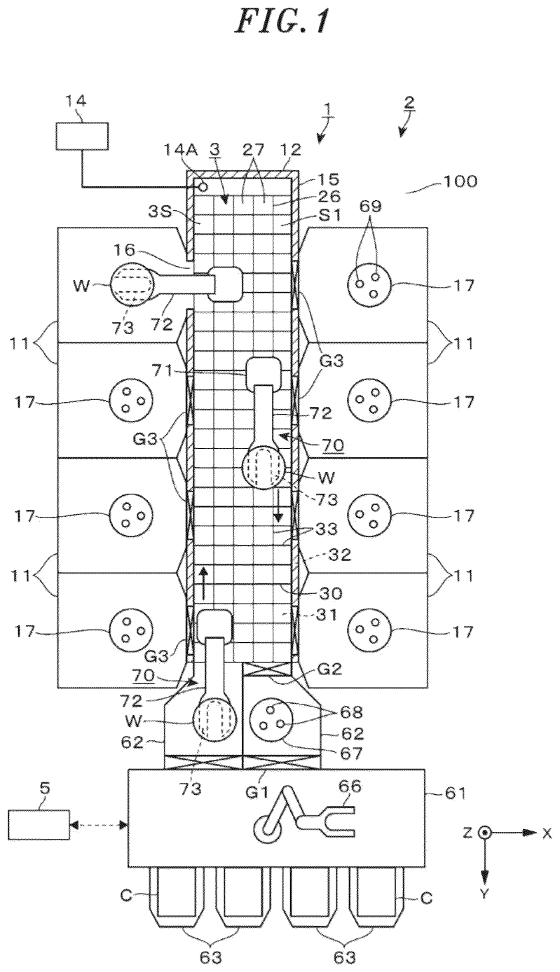

Hereinafter, an embodiment of a substrate transfer module 1 of the present disclosure forming a semiconductor processing apparatus (hereinafter referred to as a “substrate processing apparatus”) will be described with reference to FIG. 1. FIG. 1 is a plan view illustrating a configuration example of the substrate processing apparatus according to an embodiment. As shown in FIG. 1, the substrate transfer module 1 forms a multi-chamber type substrate processing apparatus 2 having a plurality of processing vessels 11 that may perform various processes on a substrate W, which is, for example, a wafer. The substrate transfer module 1 transfers the substrate W to a desired processing vessel 11 in order to perform the process on the substrate W.

In describing the substrate transfer module 1, the overall structure of the substrate processing apparatus 2 will be described first. The substrate processing apparatus 2 is installed in a clean room in a semiconductor apparatus manufacturing factory. As shown in FIG. 1, the substrate processing apparatus 2 includes an atmospheric transfer chamber 61, a load lock chamber 62, a housing 12 serving as a chamber, and a plurality of processing vessels 11, which are arranged in this order in a horizontal direction from the atmospheric transfer chamber 61. In the substrate processing apparatus 2 of this example, the processing vessel 11 is configured to process the substrate W under a vacuum atmosphere, and a transfer space S1 for the substrate W formed in the housing 12 is in the vacuum atmosphere.

When the entire substrate processing apparatus 2 will be described below, an XYZ Cartesian coordinate system shown in each drawing is used. In this coordinate system, XY directions are set in a horizontal plane. In FIG. 1, the Y direction is called a front-rear direction, and the X direction is called a left-right direction. When looking at the atmospheric transfer chamber 61 and the housing 12 arranged in the front-rear direction, a side in which the housing 12 is arranged is referred to as an inner side (rear side), and a side in which the atmospheric transfer chamber 61 is arranged is referred to as a front side. A vertical direction is set to a Z direction.

A load port 63 is provided on the inner side of the atmospheric transfer chamber 61. The load port 63 is configured as a mounting table on which a carrier C that accommodates the substrate W to be processed is mounted. For example, four carriers are installed side by side in the left-right direction. For example, a Front Opening Unified Pod (FOUP) may be used as the carrier C. The atmospheric transfer chamber 61 is in an atmospheric (normal) pressure environment, and the downflow of clean air, for example, is formed. A transfer mechanism 66, for example, a multi-joint arm, is provided in the atmospheric transfer chamber 61 and is configured to transfer the substrate W between the carrier C and the load lock chamber 62.

Between the atmospheric transfer chamber 61 and the housing 12, for example, two load lock chambers 62 are installed side by side on the left and right. The load lock chamber 62 is configured to switch between the atmospheric pressure atmosphere and the vacuum atmosphere, and includes a transmission stage 67 on which the substrate W is mounted, and a lift pin 68 that pushes up and holds the substrate W from below. For example, three lift pins 68 are provided at equal intervals along the circumferential direction of the substrate W to be held, and are configured to be lifted. The lift pins 69, which will be described later, are configured in a similar manner. A space between the load lock chamber 62 and the atmospheric transfer chamber 61, and a space between the load lock chamber 62 and the housing 12 are connected by gate valves G1 and G2, respectively, to be opened and closed.

As shown in FIG. 1, the housing 12 is long in the front-rear direction and is formed in a rectangular shape when seen in a plan view. A lower part of the housing 12 is configured as the floor 3, and a transfer space S1 for the substrate W is formed above the floor 3 within the housing 12. The housing 12 is provided with a vacuum exhaust mechanism 14, and an upstream end of a vacuum exhaust path connected to the vacuum exhaust mechanism 14 opens inside the housing 12, reducing the pressure in the transfer space S1 to create a vacuum atmosphere. In this embodiment, a total of eight processing vessels 11, four each, are connected to left and right side walls 15 of the housing 12. An opening 16 for transferring the substrate W to each processing vessel 11 is formed in the side wall 15, and each opening 16 is configured to be opened and closed by a gate valve G3. The substrate W is loaded and unloaded between the housing 12 and the processing vessel 11 through these openings 16.

Each processing vessel 11 is depressurized to the vacuum atmosphere by the vacuum exhaust mechanism (not shown). The mounting table 17 is provided inside each processing vessel 11, and a predetermined process is performed on the substrate W while the substrate is mounted on the mounting table 17. Examples of the processes performed on the substrate W include an etching process, a film formation process, an annealing process, an ashing process, etc. Each processing vessel 11 is provided with a processing module for performing the processes. For this reason, in addition to the mounting table 17, each processing vessel 11 may be provided with a heater for adjusting the temperature of the mounting table 17 and a gas supply portion such as a shower head for supplying processing gas into the processing vessel 11. Further, each processing vessel 11 may be provided with a group of gas flow devices such as a valve for introducing gas into the gas supply portion, and an exhaust mechanism such as a valve or a pump for exhausting the inside of the processing vessel 11.

For example, when the substrate W is processed using a processing gas, the processing vessel 11 is provided with the gas supply portion and the exhaust mechanism formed by the shower head or the like. When the substrate W is subjected to heat processing, the exhaust mechanism or the heater is provided. The exhaust mechanism, the heater, and the gas supply portion are not shown in the drawing. The mounting table 17 is also provided with the lift pin 69 for transferring the substrate W that is loaded and unloaded.

The transfer body 70 for transferring the substrate W is disposed within the housing 12. As shown in FIG. 1, the transfer body 70 includes a main body 71 that is placed on the floor 3 for use, and the main body 71 of this example is provided with a substrate holder 72 that horizontally holds the substrate W to be transferred. The substrate holder 72 is provided to protrude horizontally from the main body 71.

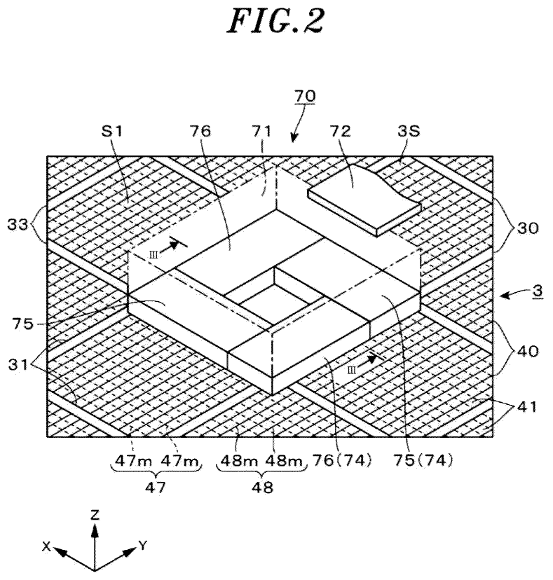

FIG. 2 is a perspective view illustrating the bottom surface of the main body 71 of the transfer body 70 and the inside of the floor 3, and also shows the upper portion of the main body 71 of the transfer body 70 and the upper surface of a tile of the floor 3, which will be described later. As will be described in detail later, the transfer body 70 is configured to be movable laterally while floating above a floor surface 3S (the upper surface of the floor 3) using a repulsive force between a magnet unit 74 provided on the bottom surface of the main body 71 and multiple electromagnets provided on the floor 3. The floating movement of the transfer body 70 prevents dust generation, thereby maintaining the transfer space S1 at a high level of cleanliness.

The lateral movement mentioned here includes the movement of the transfer body 70 in the front-back direction (Y direction) or the left-right direction (X direction) on the floor, as well as a diagonal translation movement or a rotational movement around a vertical axis on the spot. Further, the floating height of the transfer body 70 from the floor surface 3S may also be changed. Therefore, the transfer body 70 may also move in the vertical direction.

As shown in FIG. 1, for example, a front end of the substrate holder 72 is configured as a fork 73 that allows an area where three lift pins 68 and 69 are provided to be interposed between both sides. The substrate holder 72 has a length that allows the substrate W to be transferred to the mounting table 17 by opening the gate valve G3 while positioning the main body 71 within the housing 12 and inserting it into the processing vessel 11 through the opening 16.

When seen in a plan view, the length of the short side of the rectangular housing 12 is set to a dimension that allows two transfer bodies 70 each holding the substrate W to be offset from each other while they are arranged side by side. In this example, the substrates W are transferred using the plurality of transfer bodies 70 provided within the housing 12.

### <Controller>

The substrate processing apparatus 2 further includes a controller 5. The controller 5 is configured by a computer including a CPU and a storage, and controls each component of the substrate processing apparatus 2. The storage stores a program including a set of steps (commands) for controlling the operation of the processing vessel 11 and the like in various processing steps. This program is stored in a storage medium, such as a hard disk, a compact disk, a memory card, or a non-volatile memory, and is installed from there into the computer. The storage also stores a program for controlling the wafer transfer operation of the transfer body 70 or a program related to a depressurization operation for creating the vacuum atmosphere at a preset vacuum level in the transfer space S1 before the transfer operation of the substrate W.

### <Transfer Operation>

Next, an example of the transfer operation of the substrate W in the substrate processing apparatus 2 having the above-mentioned configuration will be described. First, the carrier C containing the substrate W to be processed is mounted on the load port 63. Then, the substrate W is taken out of the carrier C by the transfer mechanism 66 in the atmospheric transfer chamber 61, is loaded into the load lock chamber 62, and is transmitted to the stage 67 by the cooperation of the lift pin 68. Thereafter, when the transfer mechanism 66 retreats from the load lock chamber 62, the gate valve G1 is closed, and the interior of the load lock chamber 62 is switched from the air atmosphere to the vacuum atmosphere.

When the interior of the load lock chamber 62 becomes the vacuum atmosphere, the gate valve G2 is opened. At this time, inside the housing 12, the transfer body 70 is waiting near the connection position of the load lock chamber 62 while facing the load lock chamber 62. As described below, the transfer body 70 is moved up by magnetic levitation.

Subsequently, the substrate holder 72 of the transfer body 70 enters the load lock chamber 62, and the substrate W is received by the fork 73 of the substrate holder 72 from the stage 67 via the lift pin 68. Then, the substrate holder 72 holding the substrate W is removed from the load lock chamber 62. The transfer body 70 is retreated to a position on the side of the processing vessel 11 where the substrate W is to be processed, so that the front end of the substrate holder 72 holding the substrate W is disposed on the side of the gate valve G3.

In this way, when the front end of the substrate holder 72 reaches the side of the gate valve G3, the gate valve G3 is opened, and the main body 71 appropriately rotates, retreats, and advances to cause the fork 73 to enter the processing vessel 11 and cause the substrate W to reach the upper portion of the mounting table 17. Subsequently, the substrate W is transferred to the mounting table 17 via the lift pin 69, and the transfer body 70 is retracted from the processing vessel 11. Furthermore, after closing the gate valve G3, processing of the substrate W is started.

In this process, the substrate W mounted on the mounting table 17 is heated as necessary to a preset temperature. When a processing gas supply portion is provided, the processing gas is supplied into the processing vessel 11. In this manner, desired processing is performed on the substrate W. After the substrate W has been processed for a preset period, the heating of the substrate W is stopped, and the supply of the processing gas is stopped.

Thereafter, the substrate W is transferred in the reverse order to that of loading, and is returned from the processing vessel 11 to the load lock chamber 62. Furthermore, after the atmosphere in the load lock chamber 62 is switched to the atmospheric pressure atmosphere, the substrate W in the load lock chamber 62 is removed by the transfer mechanism 66 on the atmospheric transfer chamber 61 and returned to a predetermined carrier C.

Hereinafter, the configuration of the substrate transfer module 1 will be described in detail. The substrate transfer module 1 includes the housing 12 that defines the transfer space S1 in which the substrate W is transferred using the transfer body 70 as described above, and the vacuum exhaust mechanism 14 that evacuates the transfer space S1 to create the vacuum atmosphere. The bottom of the housing 12 is configured as the floor 3 on which a plurality of electromagnets are provided. As described above, since the substrate processing apparatus 2 is installed in the clean room, the outside of the housing 12 is in the atmospheric atmosphere. The space outside the housing 12 and exposed to the atmospheric air is referred to as an external space 100. As described later, the atmosphere of the transfer space S1 and the atmosphere of the external space 100 are separated by the floor 3, so that the transfer space S1 is configured to have high airtightness. In the transfer space S1, the substrate W is transferred in the vacuum atmosphere of 300 Pa or less, for example.

### <Transfer Body>

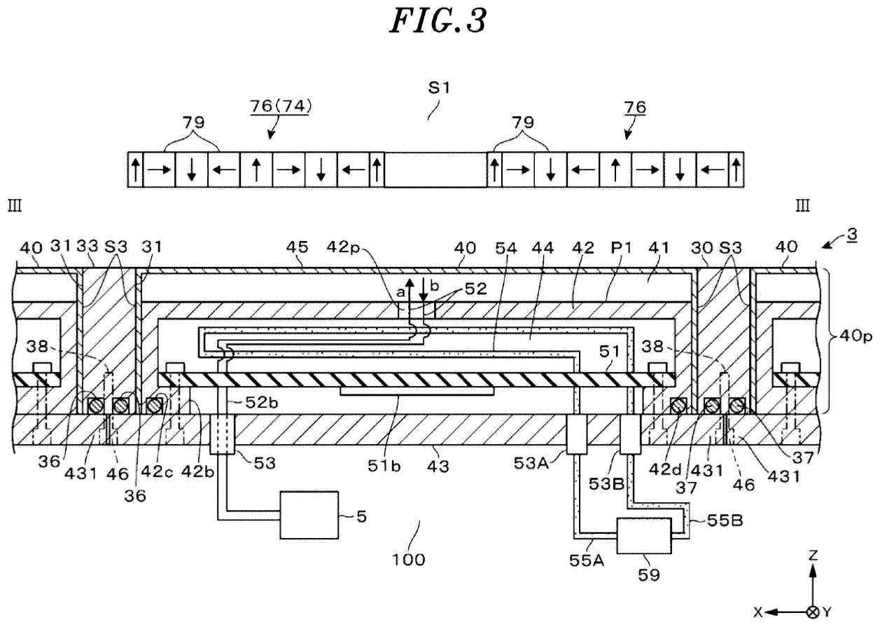

FIG. 3 is a longitudinal side sectional view taken along line III-III in FIG. 2, showing the magnet unit 74 and the tile 40 provided on the floor 3 and including the electromagnet. As shown in FIGS. 2 and 3, the main body 71 of the transfer body 70 is configured, for example, in a square shape when seen in a plan view, and the bottom surface of the main body 71 faces the floor 3. In FIGS. 2 and 3, the main body 71 is placed on the floor 3 so that each of four sides constituting the periphery of the main body 71 are parallel to the X direction or the Y direction, respectively, and the substrate holder 72 extends along the Y direction. The arrangement of the transfer body 70 may be optionally changed. However, for the convenience of explaining the configuration, the magnet unit 74 of the transfer body 70 is described as the transfer body 70 having the arrangement shown in FIG. 2.

### <Magnet Unit>

As shown in FIGS. 2 and 3, each magnet unit 74 is a plate-shaped body having the same rectangular shape in a plan view, and is composed of a plurality of magnets as described in detail later. Each of the magnet units 74 extends horizontally, with its long sides arranged along four sides of the outer frame of the main body 71. In the neighboring magnet units 74, the end of one magnet unit 74 in the longitudinal direction is located on an extension line of the other magnet unit 74 in the longitudinal direction. With this arrangement, the four magnet units 74 are configured to form an annular body and are arranged to be rotationally symmetrical around the Z axis.

In FIG. 3, the two magnet units 74 whose long sides are arranged along the X direction are referred to as first magnet units 75, while the two magnet units 74 whose long sides are arranged along the Y direction are referred to as second magnet units 76. As shown in FIG. 3 representing two second magnet units 76, each magnet unit 74 is composed of, for example, nine permanent magnets 79. The nine permanent magnets 79 are formed in a long and thin rectangular column shape extending along the Y direction and are arranged along the X direction.

In FIG. 3, the direction in which the N pole of each permanent magnet 79 is arranged is schematically indicated by an arrow. As shown in the drawing, each permanent magnet 79 is arranged so that the N pole thereof faces the Z direction or the X direction, and the direction of the N pole of an adjacent permanent magnet 79 differs by 90°. Specifically, when viewed in order from one end (+X side) to the other end (−X side) in the X direction, the N poles of the permanent magnets 79 are arranged to face +Z, −X, −Z, +X, +Z, −X, −Z, +X, +Z, and the direction of the magnetic poles changes periodically. That is, these nine permanent magnets 79 are arranged in a Halbach array, and a stronger magnetic force is formed on a lower side than on an upper side, so that a high levitation force can be obtained. The first magnet unit 75 has the same configuration as the second magnet unit 76 except that the longitudinal direction is aligned along the X direction. Therefore, the above description of the second magnet unit 76 can be interpreted as being rotated 90° around the Z axis to represent the first magnet unit 75.

### <Floor>

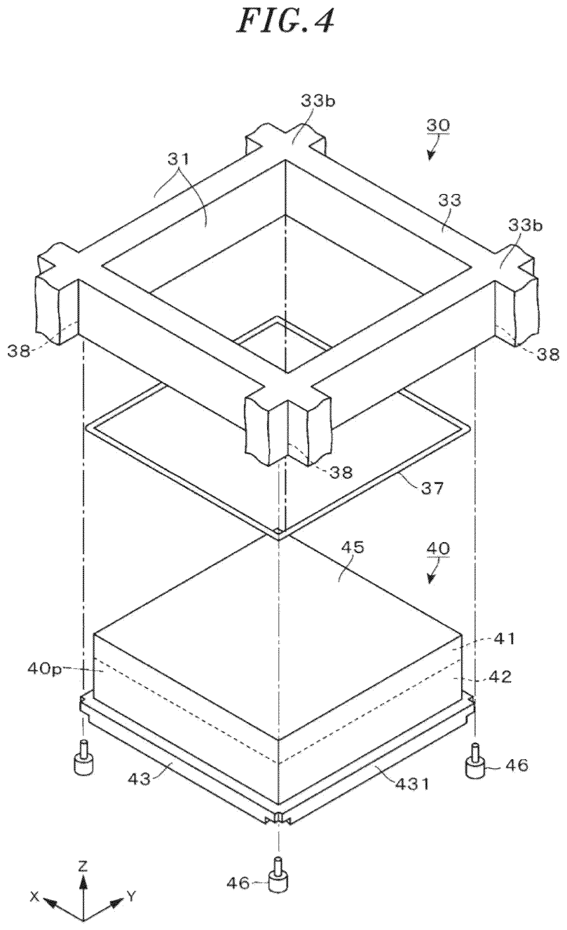

FIG. 4 is a partially exploded view of the floor 3 according to this embodiment. As shown in FIGS. 3 and 4, the floor 3, which is the bottom of the housing 12, includes a frame 30 in which a plurality of openings 31 are formed, and a plurality of tiles 40, each of which is accommodated in each opening 31. In this embodiment, the entire floor 3 is composed of the frame 30 and the tiles 40. However, for example, at the rear end of the floor 3 outside the moving area of the transfer body 70, these members are not provided, and instead, an exhaust port 14A is opened (see FIG. 1). The transfer space S1 is evacuated by the vacuum exhaust mechanism 14 such as a vacuum pump via the exhaust port 14A.

As shown in FIGS. 1 and 2, the frame 30 includes a rectangular outer frame 32 that is attached to the housing 12, and a plurality of cross members 33 that extend within the outer frame 32 in the X and Y directions. These cross members 33 arranged in a lattice pattern divide the space inside the outer frame 32 into checked patterns, thereby forming a plurality of openings 31. Each opening 31 is, for example, square in a plan view, and the openings are arranged at equal intervals in both the X and Y directions. In addition, an interval between adjacent openings 31 in the X direction is equal to the interval between adjacent openings 31 in the Y direction. The planar shapes of the openings 31 and tiles 40 are not limited to squares and may be any shapes, for example, circular shapes.

As shown in FIG. 3, in the frame 30, an annular arrangement groove 36 is formed on the lower side of the edge portion that is the outer periphery of each opening 31. The arrangement groove 36 is provided concentrically with the opening 31 and is spaced apart from the opening 31. An annular member 37 is disposed in each arrangement groove 36, so that the opening 31 is surrounded by the annular member 37. The annular member 37 is, for example, an O-ring made of an elastic material, and is a sealing member that is in close contact with the tile provided to close the opening 31 from the lower side, keeping the inside of the housing 12 airtight. As shown in FIGS. 3 and 4, screw holes 38 are provided on the lower surface of the frame 30 at positions slightly spaced from four corners of each of the openings 31. The screw holes 38 are provided on the lower surfaces of intersections 33b (see FIG. 4) of the cross members 33 that form the corners of the opening 31, and are provided to fix the tiles 40 to the cross members 33 by screwing.

<Tile forming Floor>

The tile 40 is attached to the frame 30 to cover the opening 31, thereby separating the transfer space S1, which is in the vacuum atmosphere, from the external space 100 below the floor 3. As shown in FIG. 4, for example, the tile 40 is configured in a flat hexahedron shape with a square shape in a plan view. The tile 40 is provided with a coil portion 41 in its upper area having a plurality of coils 47 and 48 that form an electromagnet, a case 42 provided below the coil portion 41, and a cover portion 43 attached to the lower surface of the case 42.

As members constituting the tile 40, the case 42 or the cover portion 43 other than the coils 47 and 48, when magnetized by the electromagnet of the coil portion 41, may cause a change in the magnetic field above, which may interfere with the movement control of the transfer body 70. To prevent it, it is preferable to use non-magnetic materials, i.e., paramagnetic or diamagnetic materials for the case 42 or the cover portion 43. Furthermore, if an eddy current is generated in the case 42 or the cover portion 43 due to a change in the magnetic field in the transfer space S1, there is a possibility that the movement control of the transfer body 70 is hindered. In order to prevent this, a relevant structure should be made of a conductor having low conductivity or non-conductor. For the above reasons, the case 42 or the frame 30 is made of, for example, aluminum (Al).

As shown in FIGS. 3 and 4, the upper and side surfaces of the coil portion 41 and the outer surface of the case 42 are covered with a coating film 45, which will be described in detail later. An upper portion 40p of the tile 40 covered with the coating film 45 has a hexahedral shape with a square shape in a plan view, as described above. The upper portion 40p of the tile 40 in a plan view has a shape that is approximately the same as the opening shape of the opening 31, but is sized so that it may be inserted and placed inside the opening 31. Therefore, when mounted on the frame 30, a gap S3 is formed between the outer surfaces of the coil portion 41 and the case 42 on which the coating film 45 is formed, and the inner wall surface of the opening 31. Since the gap S3 is open toward the upper portion of the opening 31, it communicates with the transfer space S1, and the atmosphere inside the gap S3 becomes the same as that of the transfer space S1.

The thickness of the coil portion 41 in the vertical direction is thinner than the thickness of the case 42 disposed below it. The cover portion 43 is composed of a plate-shaped member and is disposed on the lower surface of the case 42. A flange 431 is formed on the outer periphery of the cover portion to project outward from the side periphery of the case 42. The outer edge of the flange 431 is square in a plan view, and the length of each side thereof is greater than the length of each side of the opening 31, which is also square in a plan view.

The case 42 has a flat internal space 44 formed therein. A through hole 42p is formed in the upper surface of the case 42 to insert a wire 52 of the coil portion 41, which will be described later, into the internal space 44. The through hole 42p is closed by the coil portion 41 which is adhered to the upper surface of the case 42 with an adhesive P1 which will be described later. At the lower end of each side wall of the case 42, an annular fixing portion 42b is formed to protrude horizontally toward the internal space 44. The cover portion 43 is attached to the lower surface of the fixing portion 42b via a fastener such as a screw.

An annular arrangement groove 42c that opens downward is formed on the outer periphery of the lower surface of the fixing portion 42b, and an annular member 42d is disposed in the arrangement groove 42c. The annular member 42d is, for example, an O-ring made of an elastic material, and the cover portion 43 is screwed to the fixing portion 42b to hermetically seal the gap between the cover portion 43 and the case 42. In this way, the annular member 42d seals the gap between the lower surface of the case 42 and the upper surface of the cover portion 43, thereby preventing communication between the gap S3 and the internal space 44 through the gap when the frame 30 is mounted.

The cover portion 43 is attached to the case 42 to cover the internal space 44 from the lower side. The upper surface of the flange 431 of the cover portion 43 protruding laterally from the case 42 contacts the lower surface of the cross member 33 or the annular member 37. On the other hand, the lower surface of the cover portion 43 including the flange 431 contacts the external space 100. The cover portion 43 is provided with connectors 53, 53A, and 53B to penetrate a plate surface. Each of the connectors 53, 53A, and 53B constitutes a connection wire with the controller 5 described later, or a connection portion with pipes 55A and 55B disposed between the connectors and a chiller 59. Since the connectors 53, 53A, and 53B have low airtightness, the internal space 44 separated from the external space 100 by the flange 431 communicates with the external space 100 via the connectors 53, 53A, and 53B to create the atmospheric atmosphere.

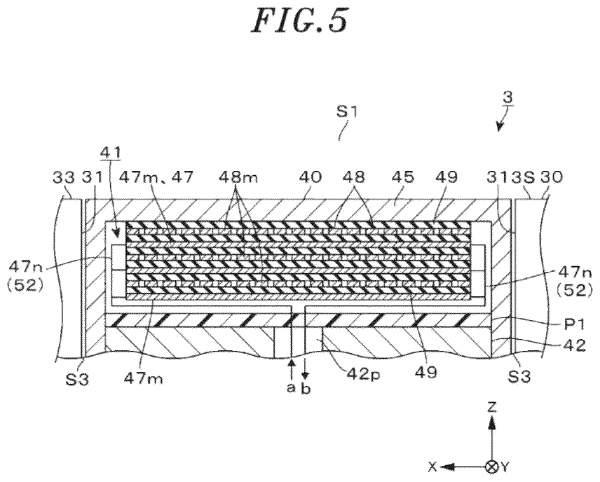

FIG. 5 is an enlarged view of the coil portion 41 in FIG. 3. In FIG. 5, in order to clarify the configuration of the coil portion 41, among the first and second coils 47 and 48 provided in the coil portion 41, a wire 47n connected to the first coil 47 is shown as a representative, and a wire connected to the second coil 48 is omitted. The wire connected to the second coil 48 may be referred to as the wire of the second coil 48 or the above-described wire.

The coil portion 41 has a lower surface thereof bonded to the upper surface of the case 42 by an adhesive P1 containing, for example, butyl rubber or epoxy resin. As described above, the coil portion 41 is provided in close contact with the upper surface of the case 42 via the adhesive P1, by inserting a plurality of wires 52 drawn out from the first coil 47 and the second coil 48 into the case 42. With this configuration, the through hole 42p is blocked by the adhesive P1. For this reason, the internal space 44 is separated from the transfer space S1, which has the vacuum atmosphere, to maintain an atmospheric state.

As shown in FIG. 5, the coil portion 41 has an electromagnet disposed along its upper surface to form the magnetic field in the transfer space S1 disposed above it. Specifically, the plurality of first and second coils 47 and 48 are arranged along the upper surface, and windings of each coil 47 or 48 are stacked in the vertical direction. The first coil 47 and the second coil 48 are composed of a plurality of conductive paths 47m and 48m, which are windings. The conductive paths 47m and 48m are arranged in layers along the upper surface of each tile 40, and the layers of the conductive paths 47m and 48m are alternately stacked and electrically isolated from each other by providing an insulating layer 49 between them.

On one side of the alternately stacked layers, the plurality of conductive paths 47m each extending in the X direction are arranged along the Y direction. The plurality of conductive paths 47m arranged in the same layer are connected in a spiral shape at both ends in the X direction by the wire (not shown) to form the first coil 47, which is a planar coil. A plurality of first coils 47 configured in this manner are arranged along the Y direction. On the other side of the alternately stacked layers, a plurality of conductive paths 48m each extending in the Y direction are arranged along the X direction. The plurality of conductive paths 48m arranged in the same layer are connected in a spiral shape at both ends in the Y direction by the wire (not shown) to form the second coil 48, which is a planar coil. A plurality of second coils 48 configured in this manner are arranged along the X direction. The alternately stacked first and second coils 47 and 48 are connected to an external power source (not shown) for each of the same type of coils 47 and 48 by the wire provided along the Z direction (FIG. 5 shows the wire 47n connected to the first coil 47).

The conductive paths 47m and 48m are formed of, for example, copper (Cu). The insulating layer 49 is formed of, for example, glass fiber, and is disposed between the conductive paths 47 m and 48 m as well as on the upper surface of the coil portion 41.

On two side surfaces along the Y direction of the coil portion 41 configured as described above, the conductive paths 47m and 48m, the ends of the insulating layer 49 in the X direction, and the wire 47n are arranged. On two side surfaces of the coil portion 41 along the X direction, the conductive paths 47m and 48m, and the above-described wire connecting each end or conductive path 48m of the insulating layer 49 in the Y direction are arranged. Further, the wire 47n connected to both ends of the first coil 47 or the above-described wire connected to both ends of the second coil 48 are disposed on the lower surface of the coil portion 41. The coil portion 41 configured as described above is integrally formed by closely adhering the conductive paths 47m and 48m adjacent to each other in the vertical direction to each insulating layer 49, and the wire 47n or the wire of the second coil 48 are closely adhered on the side surface.

The wire 47n disposed on the lower surface of the coil portion 41 and the wire of the second coil 48 are drawn into the case 42 through the through hole 42p. In the following description, the wire 47n connected to the conductive path 47m and the wire (not shown in FIG. 5) connected to the conductive path 48m may be collectively referred to as the wire 52. Further, a Hall sensor layer (not shown) in which a plurality of Hall sensors (Hall elements) for identifying the position of the transfer body 70 are arranged to be spaced apart from each other may be provided between the coil portion 41 and the case 42.

Next, turning back to FIG. 3, a configuration inside the case 42 will be described. As described above, the substrate 51 and a cooling path 54 are disposed in the internal space 44 of the case 42, which is in the atmospheric atmosphere. The cooling path 54 is disposed between the upper surface of the case 42 and the substrate 51, and cools the coil portion 41 and the inside of the case 42. One end and the other end of the cooling path 54 are connected to one ends of pipes 55A and 55B provided in the external space 100 via connectors 53A and 53B, respectively. The other ends of the pipes 55A and 55B are connected to a chiller 59 that is also provided in the exterior space 100, and the pipes 55A and 55B, the chiller 59 and the cooling path 54 form a circulation path for a refrigerant. The pipe 55A is a supply pipe for the refrigerant to the chiller 59, while the pipe 55B is a discharge pipe for the water from the chiller 59. The chiller 59 includes a pump that circulates the refrigerant, and a flow path that is connected to the pipes 55A and 55B and adjusts the flowing refrigerant to a predetermined temperature by heat exchange.

With the above configuration, the refrigerant whose temperature is adjusted by the chiller 59 is supplied to the cooling path 54 in the case 42. For this reason, in particular, the coil portion 41 that generates heat by current is cooled by heat exchange with the case 42, which is cooled by heat exchange with the refrigerant flowing through the cooling path 54, and the wire 52 inside the case 42. Therefore, the coil portion 41 is adjusted to a preset temperature range, and a change in electrical characteristics such as resistance value due to temperature is suppressed for the first coil 47 and the second coil 48. Since the displacement of the magnetic field formed on the floor 3 due to heat generation by the coil portion 41 is suppressed, the position of the transfer body 70 may be controlled with high precision. For convenience of illustration, a power supply portion 6 and the chiller 59 are shown as being located under the floor of the housing 12, but they may be located at a location away from the floor.

The substrate 51 is mounted on the inner surface of the case 42, specifically on the fixing portion 42b, via a fastener such as a screw. The substrate 51 is connected to a plurality of wires 52 extending from the coil portion 41, and is also connected to the controller 5 disposed in the external space 100 and an external power source (not shown) by wires 52b with the connector 53 interposed therebetween.

An integrated circuit chip 51b is connected to the controller 5 and the external power source, and is configured to supply current adjusted in response to a transfer control signal from the controller 5 to the first coil 47 and the second coil 48. Thus, a magnetic field is formed above the coil portion 41 to perform transfer control by the controller 5. The controller 5 may adjust the magnetic field formed in each portion on the floor 3, and may move the transfer body 70 in each direction as described with reference to FIG. 1. Although the movement of the transfer body 70 has been described as using a repulsive force, it is also possible to perform control such as fixing the transfer body 70 to a desired location on the floor 3 using an attractive force in combination with the repulsive force and by balancing the repulsive force and the attractive force. In other words, it is not limited to operation control using only the repulsive force.

When mounting the tile 40 on the frame 30, the upper portion 40p of the tile is inserted into the opening 31 from the lower side and the flange 431 disposed to overlap the lower edge of the opening 31 is screwed to the frame 30 to secure it. The annular member 37, which is the elastic body described above, is crushed between the flange 431 and the case 42, and comes into close contact with both the arrangement groove 36 of the frame 30 and the upper surface of the flange 431. Thus, as described above, the gap between the frame 30 and the tile 40 is closed at the lower edge of the opening 31, so that the atmosphere between the transfer space S1 and the external space 100 is separated.

The upper surface of the tile 40 is disposed at approximately the same height as the upper surface of the frame 30, forms the floor surface 3S with the upper surface of the frame 30, and contacts the transfer space S1. As shown in FIGS. 3 and 5, the upper surface of each flange 431 mounted on the frame 30 contacts the lower surface of the frame 30, and the side surfaces thereof are close to and face the side surfaces of other adjacent flanges 431 in the X and Y directions.

As described in detail above, the coil portion 41 is configured by alternately stacking the conductive paths 47m and 48m made of, for example, copper and the insulating layers 49 made of glass fiber, and the coil portion 41 and the case 42 are bonded together by the adhesive P1. Furthermore, the conductive paths 47m and 48m and the insulating layers 49, which are stacked, may be in close contact with each other via the adhesive. Further, each of the conductive paths 47m and 48m is connected to the wire 52. In this way, when the coil portion 41 composed of various types of components is disposed on the floor 3 of the transfer space S1, there is a risk that various contaminants may be released toward the transfer space S1, which has the vacuum atmosphere. Examples of the contaminants include pieces of glass fiber and copper ions released from the surfaces of the conductive paths 47m and 48m. In addition, organic solvent contained in the adhesive P1 and organic solvent contained in a coating material such as polyvinyl chloride, if the wire 52 is coated, may also be released as outgas (gasified organic matter). The outgas may react with moisture in the air, which may cause particles to be generated. When these contaminants or particles enter the transfer space S1 or the processing vessel 11 and adhere to the substrate W, they may contaminate the substrate W.

Therefore, in the substrate transfer module 1 of this embodiment, the coating film 45 is formed to suppress the release of contaminants from the coil portion 41 and the upper portion 40p of the tile 40 containing the adhesive P1. In detail, the coating film 45 is formed on the upper surface of the coil portion 41 and the outer surfaces of the coil portion 41 and the case 42, so that the surfaces facing the transfer space S1 and the aforementioned gap S3 (see FIG. 5) communicating with the transfer space S1 are covered by the coating film 45.

Like the materials forming the case 42 and the cover portion 43, the coating film 45 is preferably made of a non-magnetic material, a non-conductive material or a material with low conductivity so as not to interfere with the movement control of the transfer body 70. Further, the coating film 45 is preferably made of a material that does not contain a solvent, especially an organic solvent, which may cause outgas or particles, or a material that has little risk of releasing metal ions. Furthermore, the coating film 45 is preferably made of a material that is corrosion resistant at least on its surface.

Thus, the coating film 45 in this embodiment is formed of, for example, ceramic, and is preferably formed of aluminum nitride (AlN), yttrium oxide (Y₂O₃), or alumina (Al₂O₃) which has good corrosion resistance. The thickness of the coating film 45 is, for example, 3 μm to 500 μm, and is preferably as thin as possible. The coating film 45 is formed by, for example, an aerosol deposition method in which a film is formed using a room temperature impact consolidation that occurs by colliding aerosol particles of a coating film raw material at room temperature with the tile. In this case, the thickness of the coating film 45 may be 10 μm or less. The film forming method is not limited thereto, and the film may be formed by thermal spraying such as low-temperature thermal spraying. An example of film formation by the aerosol deposition method will be described later.

The effect of the tile 40 on which such a coating film 45 is formed will now be described in detail. When the transfer space S1 is depressurized by the vacuum exhaust mechanism 14 to create a vacuum atmosphere, the tile 40 is pulled upward by a pressure difference between the atmospheric pressure and the external space 100 under the floor 3. Thus, the annular member 37 is further crushed, so that the degree of contact between the lower surface of the edge of the opening 31 in the frame 30 and the upper surface of the flange 431 increases. Thereby, the transfer space S1 is sealed between the edge portion and the flange 431, so that the transfer space is air-tightly separated from the external space 100. On the other hand, since the gap S3 between the tile 40 (coil portion 41 and case 42) and the inner wall of the opening 31 is located above the sealing position by the annular member 37, as shown in FIGS. 3 and 5, it communicates with the transfer space S1.

Even in the above-mentioned state, the upper surface of the tile 40 (the upper surface of the coil portion 41) that contacts the transfer space S1 having a vacuum atmosphere, and the side surface of the tile 40 (the side surfaces of the coil portion 41, adhesive P1, and case 42) that contacts the gap S3 are covered with the coating film 45. The coating film 45 prevents the component of the coil portion 41 (the insulating layer 49 made of glass fiber, the conductive paths 47m and 48m made of copper wire, and the coated wire 52) and the layer of the adhesive P1 from coming into contact with the vacuum atmosphere. This makes it possible to prevent contaminants such as outgas and metal ions from being released from the surface. Since the coating film 45 is integrated with the coil portion 41, the adhesive P1, and the case 42, which are a base material, the coating film 45 is unlikely to crack or peel off, and the coating film 45 itself is also prevented from becoming a source of contamination that contaminates the transfer space S1.

Even if a corrosive processing gas is introduced into the transfer space S1 from the processing vessel 11, the ceramic coating film 45 is difficult to react with, so the coating film 45 is difficult to deteriorate, and contamination of the transfer space S1 can be effectively prevented for a long period of time. The corrosive gas may be, for example, a fluorine (F)-containing gas for cleaning the processing vessel 11 after the film formation process.

As a comparative example instead of the coating film 45, it is assumed that a partition wall made of a thin plate of titanium (Ti) is provided across the upper surfaces of the frame 30 and the plurality of tiles 40, and the tile 40 and the frame are separated from the vacuum atmosphere of the transfer space S1 to prevent the ingress of contaminants from the tile 40. In this case, since the space below the partition wall is partitioned from the transfer space S1 under the vacuum atmosphere, a pressure difference is generated between this space and the transfer space S1, and a load is applied to the partition wall. The partition wall subjected to a load due to the pressure difference may bulge toward the transfer space S1, resulting in deformation and damage.

In order to prevent deformation or damage to the partition wall, it is possible to reduce the pressure difference between spaces on either side of the partition wall by evacuating the space under the partition wall using the exhaust mechanism, in the same manner as the transfer space S1. However, this requires an additional exhaust mechanism, and also requires complex pressure reduction control, such as the order and adjustment of exhaust with the vacuum exhaust mechanism 14 of the transfer space S1.

In this regard, the coating film 45 formed on the tile 40 as disclosed herein can prevent contamination by the tile 40 with a simple structure, so that there is no problem caused by the installation of the partition wall. That is, compared to the case where the partition wall is provided, the coating film 45 allows the number of parts to be reduced and effectively prevents the release of contaminants with a simple structure, thereby eliminating the need for maintenance or exhaust control of the space under the partition wall.

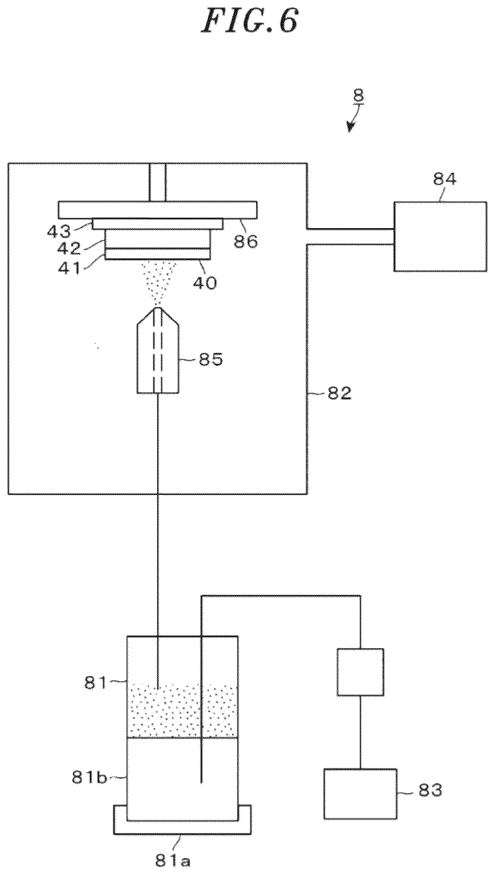

Hereinafter, a method for forming the coating film 45 will be described in brief. FIG. 6 is a schematic diagram showing a film forming apparatus 8 used for forming the coating film. The film forming apparatus 8 includes an aerosol chamber 81, a film forming chamber 82, a carrier gas supply source 83, and a vacuum exhaust mechanism 84. The aerosol chamber 81 includes a vibrator 81a and a raw material container 81b provided on the vibrator 81a. A nozzle 85 and a stage 86 are provided inside the film forming chamber 82. The stage 86 is configured to move perpendicularly to the spraying direction of the nozzle 85.

When forming the film, first, the tile 40 is installed on the stage 86 so that the lower surface of the flange 431 (the upper surface in FIG. 6) comes into contact with the stage 86. Then, the vibrator 81a is operated to introduce a carrier gas such as an inert gas at high pressure from the carrier gas supply source 83 into the raw material container 81b. The raw material container 81b contains raw material powder obtained by pulverizing the raw material of the coating film 45, for example, alumina powder when forming an alumina film. The vibration causes the raw material powder to mix with the carrier gas and become aerosolized. The film forming chamber 82 is evacuated by the vacuum exhaust mechanism 84 to reduce the pressure inside the chamber. The aerosolized raw material powder is transferred into the film forming chamber 82 by the pressure difference and sprayed from the nozzle 85.

The sprayed raw material powder collides with the upper surface (the lower surface in FIG. 6) of the coil portion 41 and is deposited thereon. At this time, the raw material powder accelerated to the sonic speed by gas transfer collides with the upper surface of the coil portion 41, is plastically deformed and densely bonded to the upper surface and the particles deposited on the upper surface, and is solidified (room temperature impact consolidation). This allows the deposition of a highly adhesive and dense film. According to the aerosol deposition method using such a room temperature impact consolidation, the film is formed at about room temperature without performing a heating process, so that the thermal effects on the coil portion 41 and electronic components composed of each semiconductor element provided on the substrate 51 can be suppressed.

By moving the stage 86 when depositing the film on the upper surface of the coil portion 41, the film may be formed uniformly and without gaps over the entire upper surface of the coil portion 41. After the film is formed on the entire upper surface of the coil portion 41, the installation direction of the coil portion on the stage 86 is changed so that the film is equally formed on four side surfaces of the upper portion 40p. Since the side surface of the upper portion 40p is composed of the respective side surfaces of the coil portion 41 and the case 42 as well as the adhesive P1, as described above, it is made of different materials or may be uneven. However, according to the aerosol deposition method, the coating film 45 may be continuously formed without gaps in the intended coating area, as with the upper surface of the upper portion 40p.

As described above, the coating film 45 is formed to cover the entire surface of the upper portion 40p of the tile 40. The coating film 45 thus formed is a thin film having a thickness of, for example, about 3 μm to 6 μm. The coating film 45 formed with high adhesion and density may sufficiently cover the tile 40 and isolate it from the vacuum atmosphere, thereby effectively suppressing the generation of outgas and the like from the tile 40. The coating film 45 thus formed is difficult to contain atmospheric atmosphere and is relatively thin, so it flexibly follows deformation caused by pressure differences in the coil portion 41 and the case 42 and can effectively prevent peeling due to the occurrence of pressure differences. Further, it is not essential to employ the aerosol deposition method using the room temperature impact consolidation in forming the coating film 45. For example, if influence on the members constituting the tile 40 is small, the coating film 45 may be formed by alumina spraying.

In this embodiment, the coating film 45 covers the entire surface of the upper portion 40p that is in contact with the vacuum atmosphere. However, the entire surface does not have to be covered. For example, in this example, it is preferable that at least the surface of the upper portion 40p is covered to such an extent that the coil portion 41 of a stacked structure including the insulating layer 49 is not damaged by the pressure difference and outgas is not released from the side surfaces of the coil portion 41 and the adhesive P1. For this reason, in this example, a portion of the side surface of the case 42 that is sufficiently separated from the adhesive P1 may not be covered.

The coating film 45 may be made of glass or a vacuum-compatible resin without being limited to ceramic. The vacuum-compatible resin is one that is intended for use in a vacuum atmosphere, such as in semiconductor or aerospace industries, has an impurity content below a preset standard, inhibits the release of outgas and metal ions in the vacuum environment, and has low water absorption. A specific example may be poly ether ether ketone (PEEK). Furthermore, the coating film 45 may be formed of a non-magnetic material with low electrical conductivity without being limited thereto. In this case, the coating film 45 may be formed of a non-magnetic metal, such as aluminum or titanium, whose surface is oxidized and passivated by alumite treatment. In this case, since the coating film is formed relatively thin, the eddy current is weak and the influence on the movement control of the transfer body 70 may be suppressed.

In the above embodiment, the floor 3 includes the frame 30 having the plurality of openings 31 and the plurality of tiles 40 disposed in the openings 31, respectively, but is not limited thereto. For example, the floor 3 may be composed of the plurality of frames 30 each having one opening 31 in which one tile 40 is placed, and the frames 30 may be connected to each other by welding or the like. The floor 3 may also be formed by a single tile formed integrally of the plurality of tiles 40.

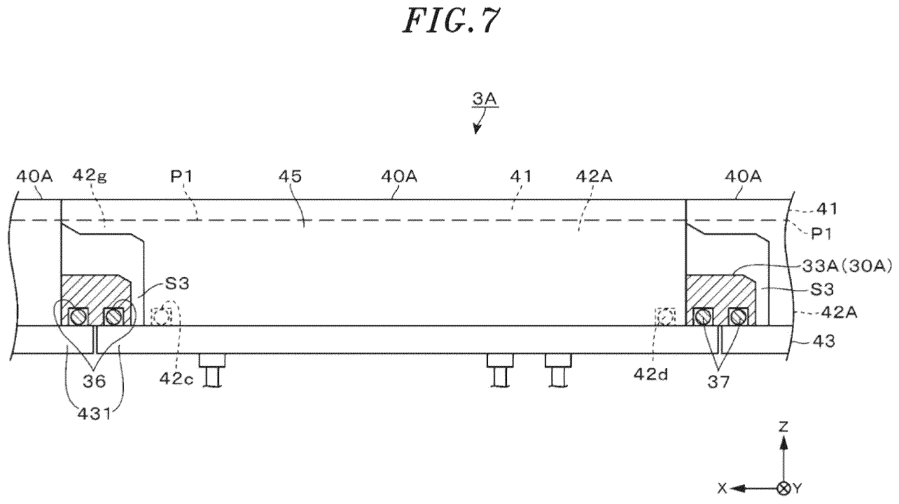

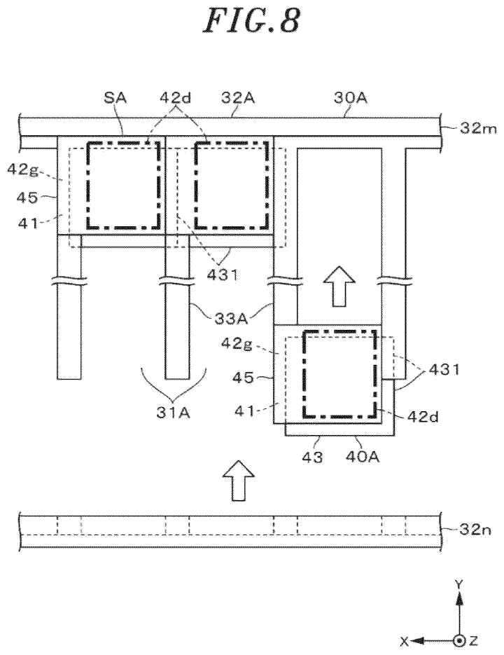

Hereinafter, a modification of the tile 40 in this embodiment will be described. FIG. 7 is a longitudinal side sectional view showing a tile 40A according to a modification in the transfer space S1 under the vacuum atmosphere. In this drawing, only a frame 30A is shown in section, and the thickness of the coating film is not shown. FIG. 8 is a plan view showing a method for attaching a tile 40A according to a modification, in which the dashed line in bold indicates an annular member 42d provided on a case 42A. In this modification, a floor 3A is configured such that a cross member 33A is disposed below the tile 40A and the upper surface of the floor 3A is not exposed to the cross member 33A. For this reason, the same magnetic field may be formed in the area directly above the cross member 33A, as in the area directly above the coil portion 41.

As shown in the side view of FIG. 7, the case 42A has an outer shape formed as a flat hexahedron, and a protrusion 42g is provided on the edge of the upper surface of the case to protrude in the positive direction of the X-axis shown in the drawing. On the other hand, as shown in the plan view of FIG. 8, the cover portion 43 is disposed to be offset in the negative direction of the Y-axis, directly below the case 42A. Therefore, before the tile 40A is attached to the frame 30A, the positive Y-direction portion of the annular member 42d is exposed downward from the lower surface of the case 42A without facing the flange 431 around the cover portion 43.

The frame 30A may be separated into two outer frames 32m and 32n. A plurality of rod-shaped cross members 33A are provided in the outer frame 32m in a comb-like shape at intervals to extend along the Y direction. An elongated rectangular opening 31A is formed between neighboring cross members 33A. The other outer frame 32n is connected after the tile 40A is installed. The tile 40A is inserted from the side, that is, from the front end of the cross member 33A, into the rectangular opening 31A formed between the cross members 33A. Thus, the cross member 33A is disposed in the gap between the protrusion 42g and the flange 431, as shown in FIG. 7. The cross member 33A is positioned so as to straddle these flanges 431 at a position where the flanges 431 of adjacent tiles 40A butt against each other. Even when the depressurization of the transfer space S1 is released and no force is applied to pull the tile 40A upward, the tile 40A attached in this manner is prevented from falling from the frame 30A because the protrusion 42g contacts the cross member 33A and the outer frame 32m.

As shown in FIG. 8, when all tiles 40A are attached to the frame 30A in the same manner as described above and the outer frame 32n is connected to fit into the front end of the cross member 33A, the frame 30A on which all the tiles 40A are attached is completed. The positive side portion of each annular member 42d in the Y-axis direction is in elastic contact with the negative side portion of the flange 431 of the adjacent tile 40A in the Y-axis direction and the upper surface of the edge of the opening 31A of the outer frame 32m.

Although no cross member is disposed between adjacent tiles 40A along the Y-axis direction, a gap along the X-direction, such as the gap between the tiles 40A and the gap SA between the tile 40 and the outer frame 32m or 32n, are blocked by the exposed portion of each of the annular members 42d on the positive side of the Y-axis. Therefore, in this modification as well, when the vacuum atmosphere of the transfer space S1 is separated from the external space 100 by the tile 40A and the frame 30A, the gap along the X direction and the surfaces contacting the transfer space S1 and the gap S3 are formed of the coating film 45, thereby suppressing the release of contaminants.

In the above-described embodiment and modification, the transfer space S1 is in the vacuum atmosphere. However, the method of covering at least the tile or 40A on the surface contacting the transfer space S1 with the coating film 45 to suppress the release of contaminants is not limited to these examples and may be applied to the substrate transfer module that transfers the substrate W under an atmospheric atmosphere at normal pressure. Even when the transfer space S1 is in the atmospheric atmosphere, it is possible to prevent contaminants, which may be released from the tile 40 or 40A, from being supplied to the transfer space S1, so that the transfer space S1 can be kept in a clean atmosphere.

It should be considered that the disclosed embodiment as an example is not limited in all points. Various forms of the embodiment may be omitted, substituted, and changed without departing from the appended claims and the spirit.

1. A substrate transfer module that constitutes a semiconductor manufacturing apparatus for processing a substrate and transfers the substrate in a transfer space having a vacuum atmosphere, the substrate transfer module comprising:
a chamber that defines the transfer space and includes a floor on which a tile is provided, the tile including an electromagnet for forming a magnetic field that acts on a magnet provided on a transfer body for transferring the substrate in the transfer space and moves the transfer body in a levitated state,
wherein a coating film is formed on at least a surface of the tile contacting the transfer space to suppress release of contaminants from components that constitute the tile.

2. The substrate transfer module of claim 1, wherein the coating film is formed of ceramic, glass, a non-magnetic metal with a passivated surface, or a vacuum-compatible resin.

3. The substrate transfer module of claim 2, wherein the ceramic is aluminum nitride, yttrium oxide, or alumina.

4. The substrate transfer module of claim 2, wherein the non-magnetic metal is aluminum or titanium.

5. The substrate transfer module of claim 2, wherein the coating film has a thickness in a range of 3 μm to 500 μm.

6. The substrate transfer module of claim 1, wherein
the electromagnet is formed by a coil portion having a stacked structure formed by alternately stacking insulating layers and conductive wires, which are windings of the coil, and
the coating film is formed on a side surface of the coil portion as well as an upper surface of the coil portion that contacts the transfer space.

7. A method of manufacturing a substrate transfer module for transferring a substrate in a transfer space having a vacuum atmosphere, the substrate transfer module constituting a semiconductor manufacturing apparatus for processing the substrate, the method comprising steps of:
forming a coating film, which is for suppressing release of contaminants from components constituting a tile, on at least a first surface of the tile, the tile including an electromagnet for forming a magnetic field that acts on a magnet provided on a transfer body for transferring the substrate in the transfer space and moves the transfer body in a levitated state, wherein the first surface is in contact with the transfer space; and
placing the tile in a lower portion of a chamber that defines the transfer space and forming the floor.

8. The method of claim 7, wherein the step of forming the coating film includes colliding aerosol particles of a coating film raw material at room temperature with the tile to form the coating film to use a room temperature impact consolidation.
